(19) United States
(12) Patent Application Publication
(10) Pub. No.: US 2006/0023434 A1
(43) Pub. Date: Feb. 2, 2006

(54) Latch system

(76) Inventors: Bogdan Andrei, Lisle, IL (US); Loreta Sadauskiene, Plainfield, IL (US)

Correspondence Address: MOLEX INCORPORATED, 2222 WELLINGTON COURT, LISLE, IL, 60532, US

(21) Appl. No.: 10/903,544

(22) Filed: Jul. 31, 2004

(51) Int. Cl. H05K 5/02

(52) U.S. Cl. 361/756; 361/725

(57) ABSTRACT

A latching mechanism that is convenient to use and able to last through many duty cycles. The latching mechanisn includes a housing having one or more spring biased latches extending outwardly from the housing to automatically lock the housing into place during installation of the device. The latching system further includes an actuating sleeve configured to retract the latches when the actuating sleeve is pulled forward for easy and quick removal of the device.

### FIELD OF THE INVENTION

The present invention relates generally to latches and, more particularly, to latching systems for electronic and mechanical devices.

### BACKGROUND OF THE INVENTION

Latches are used in a wide variety of electronic equipment and serve to securely attach a connector or module to the base device. Latches take on various forms, depending on the particular configuration of the electronic equipment. For example, a serial port in a personal computer is typically configured so as to receive the threaded ends of a thumbscrew, which is attached to the serial port cable. The end user places the head of the cable onto the serial port and then turns the thumbscrew so as to engage the threaded receiving end. Parallel ports operate in a similar manner.

Latches are also found in fiber optic ferrules. These latches secure the ferrule to the adapter so as to prevent the ferrule from falling out. For example, the MT-RJ connector by Molex Incorporated includes a latch that is similar to the RJ-45 type latch found in commonly available telephone cords.

Depending on the particular application or device being used, latches may be fairly sophisticated so as to facilitate the ease of insertion or removal of a latched device. Unfortunately, there exist many latches that are cumbersome to operate and/or require a great deal of intervention by the user. In addition, many latches are unable to successfully withstand repeated insertions and removals without wearing out or breaking.

### DESCRIPTION

In order to address the need for a latching mechanism that is convenient to use and able to last through many duty cycles, a latching system is provided as follows: a housing, such as for an optoelectric transceiver, having one or more spring biased latches extending outwardly from the housing and an actuating sleeve configured to retract the latches when the actuating sleeve is pulled.

This type of a system precludes the need for the tedious and time consuming method of turning thumbscrews, for example. The insertion and removal process of the latching mechanism described herein allows for removal and insertion of the device using natural and intuitive motions. One simply grips the front end and pulls. The internal mechanism, as described in detail further below, causes the latching mechanism to retract and the module to be easily removed. A particular advantage of such a system is that the user is not required to use miniature screw drivers or other special tools during insertion and removal. A simple, single operation is used to insert and/or remove any device incorporating the present latching system. Another important advantage is the speed at which the insertion and removal process is executed.

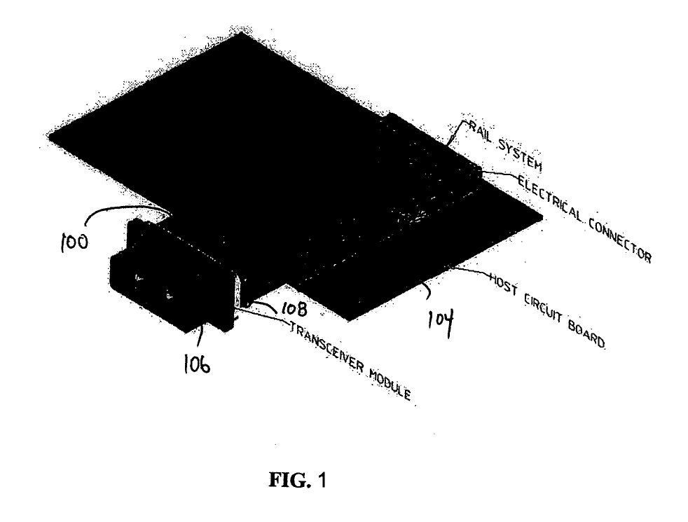

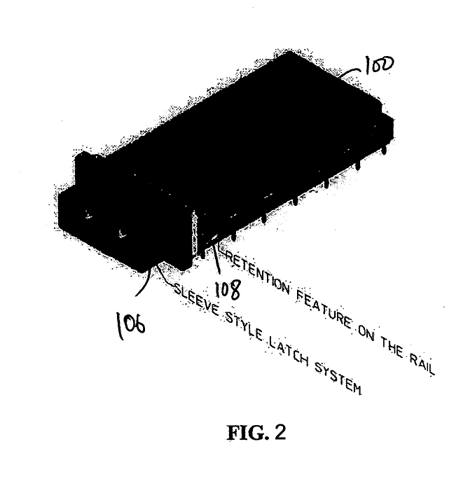

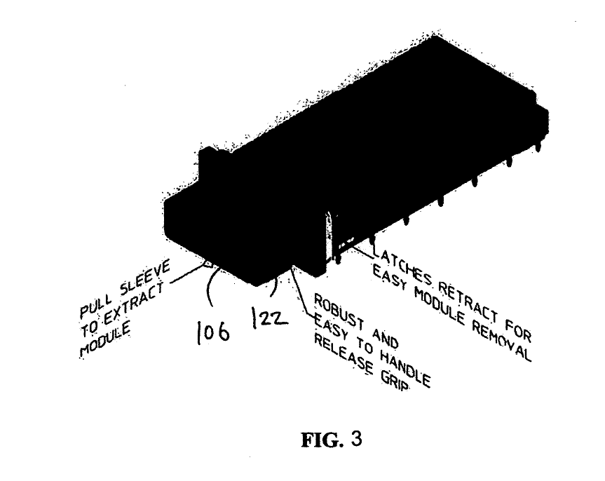

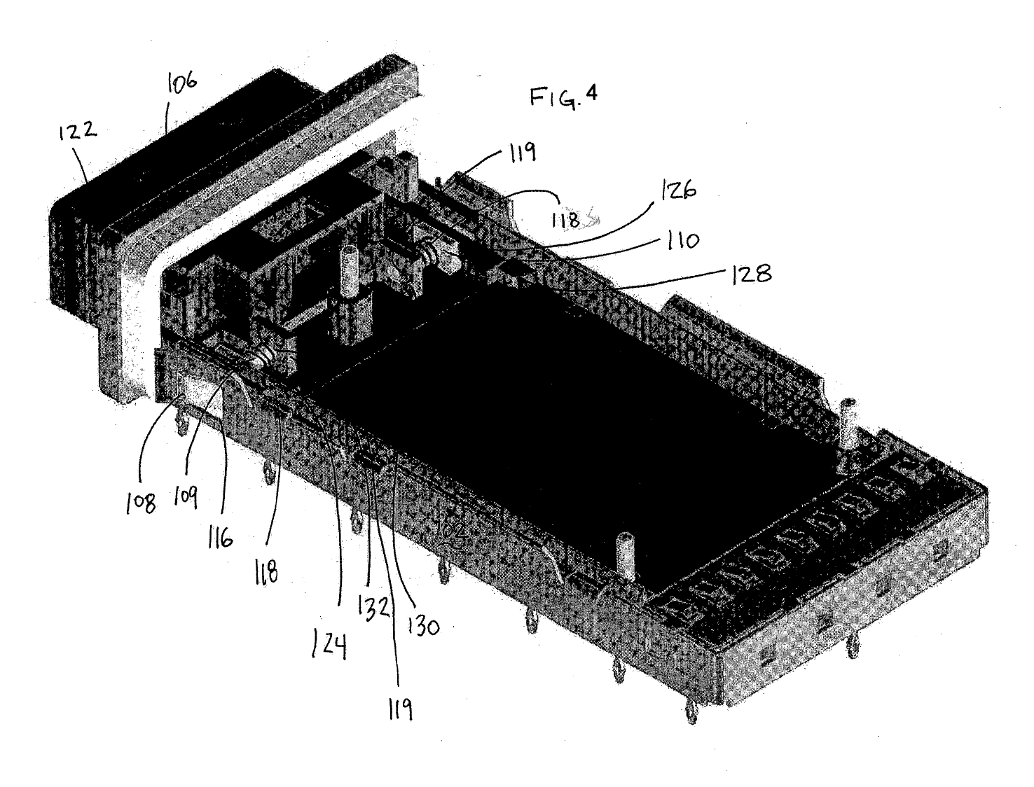

Referring to FIGS. 1-4, a latching device is shown that is used for releasing a pluggable transceiver module 100 from a rail system 102 that is mounted on a host circuit board 104. The latching device described herein provides a robust solution to overcome the forces incurred by the electrical connector during extraction. Specified is a standardized retention feature on the rail system for the module to engage upon insertion. It is to be noted that the latching device shown and described herein may also be used equally as effectively in many other latching devices and is not to be limited to pluggable transceiver modules.

FIG. 5 shows the latching system in greater detail. In particular, the latching system includes an actuating sleeve 106 and handle release grip 122. As can be seen, the handle release grip is either molded as a single piece with the actuating sleeve 106 or is attached to it and moves in concert with it. Advantageously, the handle release grip 122 is formed with raised sidewalls so that an end user is able to easily grasp the handle release grip 122. Thus, by pulling the handle release grip 122, the actuating sleeve 106 is also pulled outwardly.

A pair of rearwardly extending arms 124, 126 is provided inside the device and is either integrally formed or in physical contact with the handle release grip 122 and the actuating sleeve 106. A pair of locking latches 110 is provided on each side of the device. Each locking latch 110 is formed with an angled wedge shaped head 108, which may extend out the side of the rail 112 through a retention aperture 116.

The wedge shaped head 108 is connected to the proximate end of a post 109. The distal end of the post 109 engages an aperture 119 in an upright retaining post 132. A spring 118 is wrapped around the post such that it presses against the retaining post 132, thereby biasing the wedge shaped head 108 outwards. A pair of stops 128 prevents the arms 124, 126 from extending too far into the device. The stops 128 are also used as pressure points to help push the device into the rail 102.

In operation, by pulling the actuating sleeve 106 on the transceiver 100, the two symmetrically opposed spring-biased locking latches 108, 110 are retracted flush with the module 100 sides. This is made possible through the use of angled head portions on each of the arms 124, 126. The angled heads of each arm 124, 126 engage one each of the angled wedge shaped heads 108 of the locking latches 110. Therefore, when the handle release grip is pulled outwardly, the angled heads of the arms 124, 126 engage the angled wedge shaped heads 108. This causes the angled wedge shaped heads 108 to retract into the device and also compresses the springs 118. This allows the module 100 to be easily removed from the rail 102.

Once the pressure on the arms 124, 126 is released, the springs once again automatically bias the latches outwardly. Therefore, during insertion, the latches 108, 110 engage the retention apertures 114, 116 of the rail 112. Thus, it can be seen that a unique feature of the locking latches 108, 110 is that they are automatically biased into their positions by a positive force provided by the springs 118, 120.

It should be understood that the implementation of other variations and modifications of the invention in its various aspects will be apparent to those of ordinary skill in the art, and that the invention is not limited by the specific embodiments described. It is therefore contemplated to cover by the present invention, any and all modifications, variations, or equivalents that fall within the spirit and scope of the basic underlying principles disclosed and claimed herein.

What is claimed is:

1. An optoelectric transceiver housing system, comprising:
a housing;
one or more spring biased latches extending outwardly from the housing;
an actuating sleeve configured to retract the latches when the actuating sleeve is pulled.

2. The optoelectric transceiver housing system of claim 1, wherein the actuating sleeve comprises a pair of rearwardly extending arms for retracting the latches.

3. The optoelectric transceiver housing system of claim 1, wherein the actuating sleeve is configured with one or more contoured edges for facilitating grasping of the actuating sleeve.

4. The optoelectric transceiver housing system of claim 1, further comprising a rail having apertures, the apertures configured to engage the one or more spring-biased latches.
